(19) United States
(12) Patent Application Publication
(10) Pub. No.: US 2026/0173494 A1
(43) Pub. Date: Jun. 18, 2026

(54) Gallium Nitride Transistor Formation

(71) Applicant: Applied Materials, Inc., Santa Clara, CA (US)

(72) Inventors: Michael PETERS, Beaverton, OR (US); Michel EL KHOURY MAROUN, Palo Alto, CA (US)

(21) Appl. No.: 18/986,309

(22) Filed: Dec. 18, 2024

(51) Int. Cl. H10D 80/20; H01L 23/00; H01L 25/00; H01L 25/07

(52) U.S. Cl. CPC H10D 80/251; H10W 90/00; H10W 80/211; H10W 80/312; H10W 80/327; H10W 90/792

(57) ABSTRACT

A method of forming transistor structures uses existing gallium nitride formation processes to form dies that are then reconstituted into a larger wafer format to enable the use of existing large wafer manufacturing tooling for scaling. In some embodiments, the method comprises forming a reconstituted wafer by bonding dies having gallium nitride (GaN) transistor structures to a carrier wafer and hybrid bonding the reconstituted wafer to a silicon wafer having silicon-based transistor control structures. The dies may include high electron mobility transistors (HEMTs) formed on, for example, a silicon substrate, a silicon carbide substrate, or a sapphire substrate.

### FIELD

Embodiments of the present principles generally relate to semiconductor processing of semiconductor substrates.

### BACKGROUND

Gallium nitride is used to form devices such as high frequency transistors for fast switching and amplification applications. The gallium nitride is formed by epitaxial growth processes that are optimized for smaller wafer sizes (e.g., 150 mm or 200 mm diameter wafers). Most manufacturing entities have invested large amounts of capital and time in acquiring tooling that will produce high quality epi growth at the 150/200 mm wafer sizes. The epi growth of gallium nitride does not scale well and changing the wafer to a larger size means that the epi growth parameters and techniques will need to be completely re-engineered which is costly and time consuming. Even with time and funding, the quality of the gallium nitride epi growth will be subpar compared to currently optimized growth techniques for the smaller wafer sizes. In addition, the inventors have observed that using gallium nitride structures on smaller wafer sizes limits the use of larger wafer manufacturing tooling that can be used to further scale the gallium nitride structures.

Accordingly, the inventors have provided methods for improved manufacturing of gallium nitride structures that also enables the use of large wafer toolsets for gallium nitride transistor structures.

### SUMMARY

Methods for forming gallium nitride transistors using reconstituted wafers and silicon-based logic controls are provided herein.

In some embodiments, a method of forming transistors may comprise forming a reconstituted wafer by bonding dies having gallium nitride (GaN) transistor structures to a carrier wafer and hybrid bonding the reconstituted wafer to a silicon wafer having silicon-based transistor control structures.

In some embodiments, the method further includes dies that have GaN transistor structures that are high electron mobility transistors (HEMTs) formed on a silicon substrate, a silicon carbide substrate, or a sapphire substrate, dies that are coated with an oxide bonding layer on a backside, a carrier wafer that is coated with an oxide bonding layer on a topside, a backside of the dies that are fusion bonded to the topside of the carrier wafer, and/or an interdie dielectric gapfill process that is performed on the carrier wafer after the dies are fused to the carrier wafer to form the reconstituted wafer containing the dies, an oxide bonding layer that is formed from tetraethyl orthosilicate (TEOS) oxide material, a reconstituted wafer that is approximately 300 mm in diameter, GaN transistor structures that are processed in-situ in the reconstituted wafer to have transistor gate lengths that are approximately 50 nm or less, a reconstituted wafer that undergoes extreme ultraviolet lithography prior to being hybrid bonded to the silicon wafer, a reconstituted wafer that undergoes a preclean or a passivation process to further form the GaN transistor structures on the reconstituted wafer prior to being hybrid bonded to the silicon wafer, a first oxide bonding layer that is formed on a first topside of the reconstituted wafer and a second oxide bonding layer that is formed on a second topside of the silicon wafer prior to hybrid bonding, at least one source, drain, and gate that are formed on the reconstituted wafer on at least one die of the dies prior to forming the first oxide bonding layer, contacts that are formed through the first oxide bonding layer to underlying structure of the GaN transistor structures prior to the reconstituted wafer being bonded to the silicon wafer, a carrier wafer that is removed after bonding the reconstituted wafer to the silicon wafer, and/or GaN transistor structures that form RF power amplifiers or RF power switches and silicon-based transistor control structures that form logic circuitry to control the RF power amplifiers or the RF power switches.

In some embodiments, a gallium nitride transistor may comprise a gallium nitride channel layer, an aluminum gallium nitride barrier layer formed on the gallium nitride channel layer, a source contact and a drain contact electrically connected to the gallium nitride channel layer, a gate positioned horizontally between the source contact and the drain contact on the aluminum gallium nitride barrier layer where the gate has a length that is approximately 50 nm or less, and where the gallium nitride transistor is formed by forming a reconstituted wafer by bonding dies having gallium nitride (GaN) transistor structures to a carrier wafer and hybrid bonding the reconstituted wafer to a silicon wafer having silicon-based transistor control structures.

In some embodiments, the gallium nitride transistor further includes dies that are high electron mobility transistors (HEMTs) formed on a silicon substrate, a silicon carbide substrate, or a sapphire substrate, a gallium nitride transistor that includes an oxide bonding layer, and/or a gallium nitride transistor that is an RF power amplifier or an RF power switch with silicon-based logic circuitry to control the RF power amplifier or the RF power switch.

In some embodiments, a non-transitory, computer readable medium having instructions stored thereon that, when executed, cause a method of forming transistors to be performed, the method may comprise forming a reconstituted wafer by bonding dies having gallium nitride (GaN) transistor structures to a carrier wafer and hybrid bonding the reconstituted wafer to a silicon wafer having silicon-based transistor control structures.

The method may further include dies that are coated with an oxide bonding layer on a backside, a carrier wafer that is coated with an oxide bonding layer on a topside, dies that are fusion bonded to the carrier wafer, and an interdie dielectric gapfill process that is performed to form the reconstituted wafer containing the dies and/or GaN transistor structures that are processed in-situ in the reconstituted wafer to have transistor gate lengths are approximately 50 nm or less.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of forming GaN transistors in accordance with some embodiments of the present principles.

FIG. 2 depicts a cross-sectional view of a GaN device wafer with transistor structures in accordance with some embodiments of the present principles.

FIG. 3 depicts a cross-sectional view of GaN transistor structure dies singulated from the GaN device wafer in accordance with some embodiments of the present principles.

FIG. 4 depicts a cross-sectional view of a carrier wafer in accordance with some embodiments of the present principles.

FIG. 5 depicts cross-sectional views of GaN transistor structure dies bonded to a carrier wafer in accordance with some embodiments of the present principles.

FIG. 6 depicts a cross-sectional view of interdie gapfill material deposited on a carrier wafer in accordance with some embodiments of the present principles.

FIG. 7 depicts a cross-sectional view of a carrier wafer after planarizing the interdie gapfill material in accordance with some embodiments of the present principles.

FIG. 8 depicts a cross-sectional view of gates and sources/drains formed on GaN transistor structures on a carrier wafer in accordance with some embodiments of the present principles.

FIG. 9 depicts a cross-sectional view of dielectric material and oxide bonding layer formed on a carrier wafer in accordance with some embodiments of the present principles.

FIG. 10 depicts a cross-sectional view of contacts formed into the oxide bonding layer and the dielectric material on a carrier wafer in accordance with some embodiments of the present principles.

FIG. 11 depicts a cross-sectional view of a silicon-based wafer with transistor control structures in accordance with some embodiments of the present principles.

FIG. 12 depicts a cross-sectional view of a silicon-based wafer with transistor control structures which is hybrid bonded to a carrier wafer with GaN transistor structures in accordance with some embodiments of the present principles.

FIG. 13 depicts a cross-sectional view of carrier wafer material removal from a bonded wafer in accordance with some embodiments of the present principles.

FIG. 14 depicts a cross-sectional view of an oxide bonding layer removal from a bonded wafer in accordance with some embodiments of the present principles.

FIG. 15 depicts a cross-sectional view of external contacts formed to the GaN transistor in accordance with some embodiments of the present principles.

FIG. 16 depicts a cross-sectional view of GaN transistors singulated from a bonded wafer in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods enable advanced tooling designed for large silicon wafers to be used to improve the scaling of transistor structures formed from high quality, epitaxially grown, gallium nitride (GaN) from small diameter wafers. The techniques herein enable processing of 300 mm GaN RF devices without having to convert GaN epi lines to 300 mm in order to use 300 mm wafer toolsets. Where gate scaling is currently limited to electron beam lithography on 150 mm wafers, the present methods enable the use of, but not limited to, deep ultraviolet (DUV) or extreme ultraviolet (EUV) processes for gate length scaling below 100 nm. The present principles advantageously provide an alternative to 300 mm GaN epi reactors without requiring any 300 mm epi processes. Moreover, the techniques beneficially enable the combining of the power handling and high frequency performance of GaN transistors with the signal processing, logic, and high-volume manufacturing of complementary metal-oxide-semiconductor (CMOS) processes.

Currently, there is a lack of widespread availability of 300 mm GaN wafers. What is available is in very limited supply and is inferior in quality to widely available 150/200 mm GaN wafers. Manufacturers are resistant to moving to 300 mm GaN wafers, as the epi growth optimization learning time is extreme. The quality of the epi grown on 300 mm GaN cannot match what is currently available with smaller wafer epi growth. In addition, much of the expensive 300 mm GaN wafer may be wasted as devices may not necessarily be formed on the entire wafer, driving up the cost of the individual devices produced from such a GaN wafer. The present methods make use of GaN dies from currently available 150 mm or 200 mm substrates for only the required transistor functions which minimizes the use of the expensive GaN substrate material.

Moreover, with the present processes, there is no need to develop 300 mm epitaxial processes, and, thus, no need for 300 mm metal-organic chemical vapor deposition (MOCVD) tooling. Forming a 300 mm reconstituted wafer with the GaN dies and integrating with 300 mm CMOS toolsets allows for new transistor gate and lithography processing not available on the current 150/200 mm toolsets used for GaN circuits. The methods of the present principles form GaN structures on smaller GaN wafers (e.g., 150/200 mm) which are then diced to form dies. The dies are then bonded to a carrier wafer to form a reconstituted wafer (e.g., 300 mm wafer). The wafer can then be used on larger wafer tool sets, for example but not limited to, to enable lithography techniques to scale the gate length to less than 100 nm. The smaller the gate length of the transistor, the higher the frequencies that are obtainable from the transistor.

GaN devices have performance advantages over silicon for power switching. However, GaN devices require a pre-driver circuit to control the switching. Using connection techniques such as bond wire, PCB connections, etc. cause parasitic losses that degrade performance of the GaN device. The present methods provide a larger GaN reconstituted wafer (e.g., 300 mm) that can be used in advanced tooling to form the higher frequency devices. The larger reconstituted wafer can then be hybrid bonded to a large CMOS logic silicon-based wafer (e.g., 300 mm) which includes devices that perform the pre-driver functions to control the GaN transistor devices. The hybrid bonding reduces connection lengths between the GaN transistor and the control circuitry, reducing parasitic losses and increasing performance of the transistor (shorter connections enable faster signals). In addition, the present methods produce the higher performing GaN transistors at a significantly reduced cost compared to using 300 mm GaN wafers or using 300 mm GaN wafers on which both the transistor and logic control circuitry are formed.

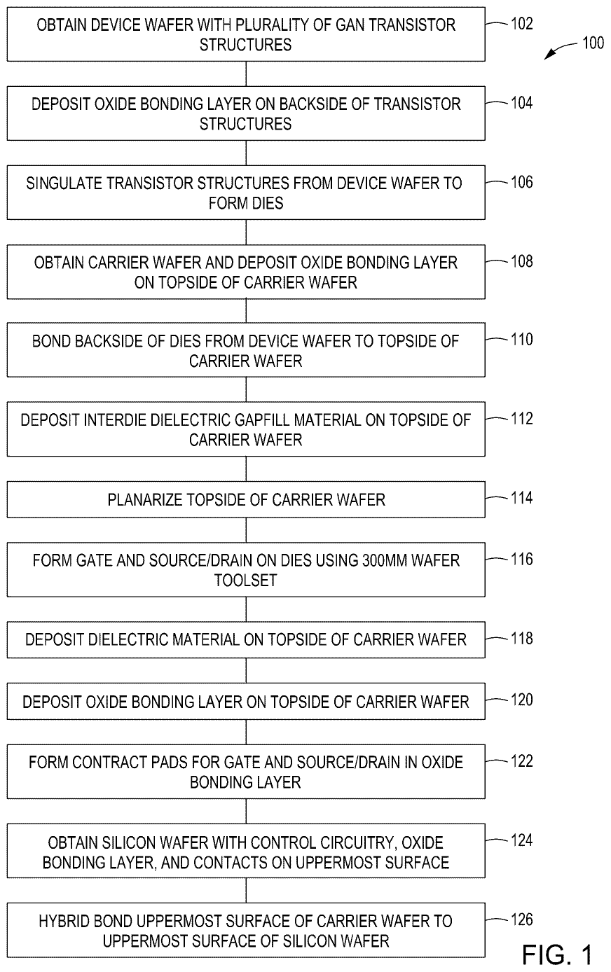

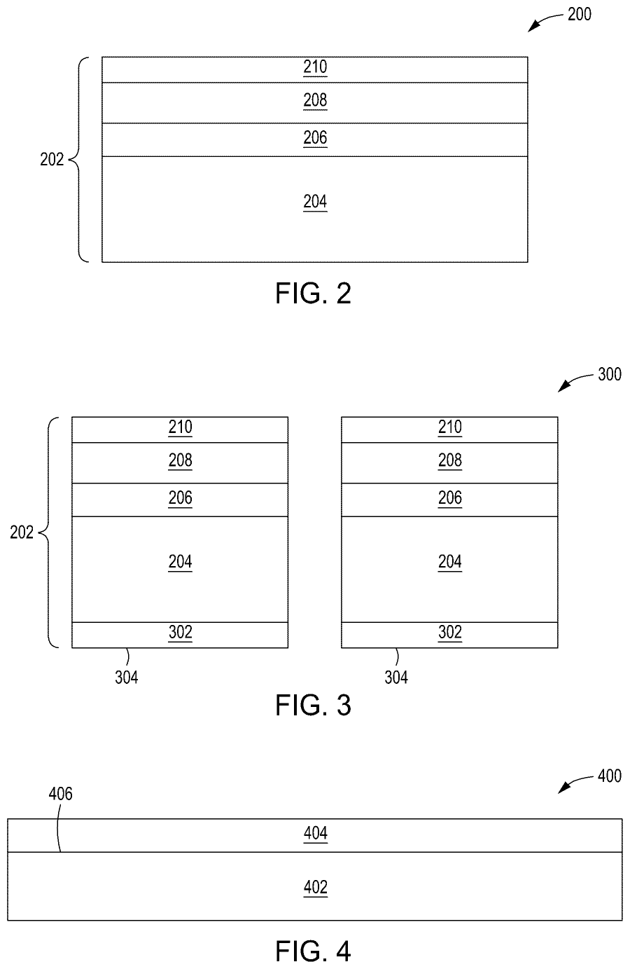

In FIG. 1 is a method 100 of forming GaN transistors. References are made to FIGS. 2-16 in the discussion of the method 100. In block 102, a GaN wafer is obtained that contains a plurality of transistor structures 202 such as, but not limited to, high electron mobility transistor (HEMT) structures, formed on a topside of a substrate 204 as depicted in a view 200 of FIG. 2. In some embodiments, the substrate 204 may be a silicon substrate, a silicon carbide substrate, or a sapphire substrate, and the like. In some embodiments, the substrate 204 may comprise silicon with a (111) crystal orientation to enable high quality epitaxial GaN growth such as epi deposition in an MOCVD reactor. The substrate 204 may have, for example, a 150 mm or 200 mm or smaller diameter that is compatible with existing GaN epi process tooling. In some embodiments, the transistor structures 202 may include a buffer layer 206, a GaN channel layer 208, and an aluminum GaN (AlGaN) barrier layer 210 on the substrate 204. The buffer layer 206 is deposited on the substrate 204 and then the GaN channel layer 208 is deposited on the buffer layer 206 using an epi growth process (e.g., MOCVD, etc.). The GaN channel layer 208 forms the material to be used for the channel between the source and drain of a transistor. The AlGaN barrier layer 210 is then deposited on the GaN channel layer 208. At a later stage, a gate is formed on the AlGaN barrier layer 210 to enable control of the flow through the transistor channel between the source and the drain.

The order of blocks 104 and 106 may be reversed in the method 100. In block 104, an oxide bonding layer 302 is deposited on the backside of the transistor structures 202 (exposed substrate backside) prior to or after singulation is performed (as depicted in a view 300 of FIG. 3). In some embodiments, the oxide bonding layer 302 or coating may be, but is not limited to, a tetraethyl orthosilicate (TEOS) oxide bonding layer and the like. The oxide bonding layer 302 enhances subsequent fusion bonding to a carrier wafer with a similar oxide coating. In block 106, which may occur before or after the deposition of the oxide bonding layer 302, the transistor structures 202 are singulated from the GaN wafer to form dies 304, each die containing a portion of the transistor structures 202. In some embodiments, thinning of the transistor structures 202 may also occur prior to or after singulation to further prepare the dies 304. If the oxide bonding layer 302 has not been formed prior to singulation, the oxide bonding layer 302 or coating may be deposited on a backside (exposed substrate backside) of the dies 304.

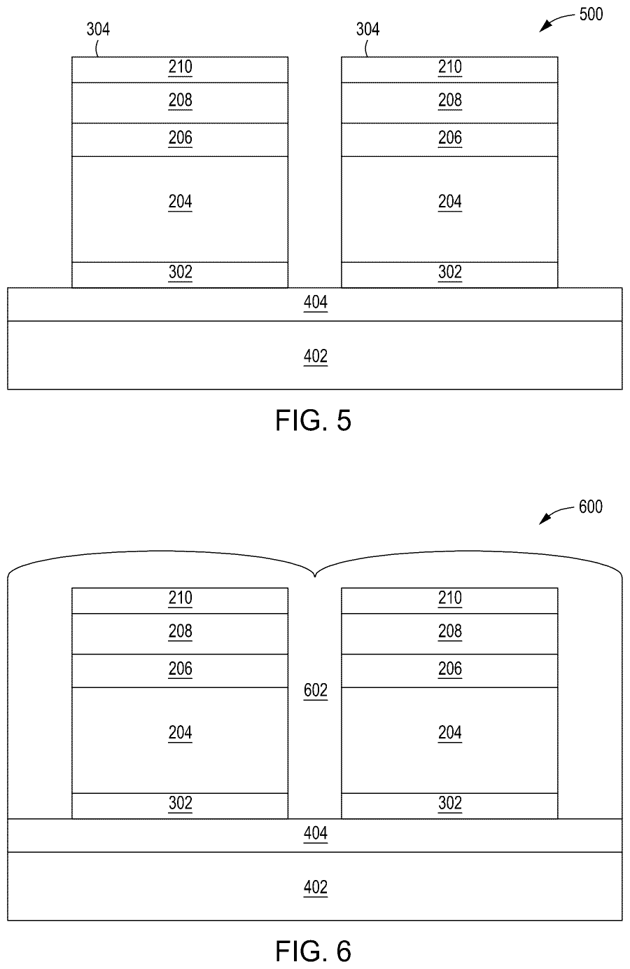

In block 108, a carrier wafer 402 is obtained as depicted in a view 400 of FIG. 4. In some embodiments, the carrier wafer 402 may have a diameter of approximately 300 mm and enable the carrier wafer 402 to be subsequently processed in 300 mm silicon-based tooling. The carrier wafer 402 serves as a basis for forming a reconstituted wafer with the dies 304 from the GaN wafer. The reconstituted wafer may be larger in diameter than the GaN wafer. Also in block 108, a second oxide bonding layer 404 is deposited on a topside 406 of the carrier wafer 402. In some embodiments, the second oxide bonding layer 404 may be, but is not limited to, a tetraethyl orthosilicate (TEOS) oxide bonding layer and the like. In block 110, the backside of the dies 304 with the oxide bonding layer 302 are bonded to the topside 406 of the carrier wafer 402 with the second oxide bonding layer 404 in a fusion bonding process as depicted in a view 500 of FIG. 5. The dies 304 may be picked and placed at any position on the carrier wafer 402, allowing for both known good dies to be used to enhance yields but also to minimize usage of expensive GaN material in areas where such material is not needed. The positioning of the dies 304 on the carrier wafer 402 may also coincide with positioning of transistor logic circuitry in CMOS silicon-based wafers that will be subsequently hybrid bonded to processed reconstituted wafers containing the dies 304 (discussed below).

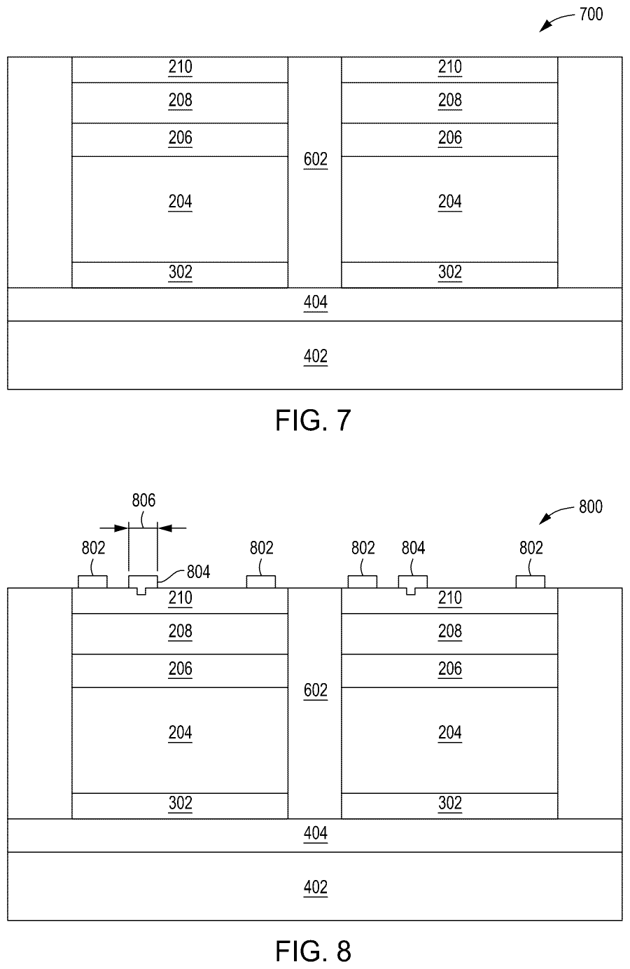

In block 112, interdie gapfill material 602 is deposited onto the carrier wafer 402 to form a reconstituted wafer as depicted in a view 600 of FIG. 6. The interdie gapfill material 602 may be deposited in, but is not limited to, a plasma enhanced CVD (PECVD) chamber and the like. In block 114, the topside of the carrier wafer 402 is planarized as depicted in a view 700 of FIG. 7. The planarization removes excess interdie gapfill material to expose the AlGaN barrier layer 210 of the transistor structures. The planarization provides a flat surface on the wafer for further processing such as, for example, for lithography processes. In some cases, the planarization may include grinding and/or chemical mechanical planarization (CMP) processes to make the carrier wafer 402 (reconstituted wafer) ready for front-end-of-line (FEOL) processing. In block 116, the FEOL processing may include, but is not limited to, formation of the gate 804 and source/drain 802 on the dies 304 using silicon-based tooling such as, but not limited to, tooling for 300 mm wafers as depicted in a view 800 of FIG. 8. The 300 mm tooling may include existing preclean processes and/or passivation processes not currently available for smaller diameter wafers.

The 300 mm tooling may also include lithography processes such as, but not limited to, extreme ultraviolet (EUV) lithography and/or deep ultraviolet (DUV) processes and the like that enable scaling of a transistor gate length 806 to approximately 100 nm or less. In some embodiments, the transistor gate length 806 may be approximately 50 nm or less. The gate length for RF devices needs to be extremely small to allow for high-speed switching. Currently, no 150/200 mm process chambers exist that can do gate lengths as small as 300 mm lithography tooling. The gate scaling requires state-of-the-art lithography not available for smaller 150/200 mm wafers. Higher resolution lithography tools such as electron beam lithography are very difficult to work with in a high-volume manufacturing environment and are limited to smaller 150/200 mm wafers.

In some embodiments, the FEOL processing may include, but is not limited to, GaN and AlGaN etching, atomic layer deposition (ALD) of, but not limited to, aluminum nitride (AlN) and aluminum oxide (Al₂O₃), passivation processes using, but not limited to, ALD AlN and Al₂O₃ deposition, and/or metal contact formation using, but not limited to, physical vapor deposition (PVD) of, but not limited to, titanium aluminide (TiAl) and the like. The 300 mm reconstituted wafer size also enables integrated tooling to be used for GaN transistor formation to allow for precleaning and passivation processes without exposure to atmospheric conditions (chamber to chamber movement under a vacuum state). The integrated precleaning and passivation enables prevention of current collapse in the GaN RF devices. Current collapse is the reduction of drain current under high RF power operation caused by trapped electrons in the transistor's interface layers which leads to lower channel carrier density and limits the transistor's power output. The precleaning and passivation ensures that the interface layers are substantially free from defects and/or oxidation and the like to aid in preventing current collapse. Additional FEOL processing may also be performed.

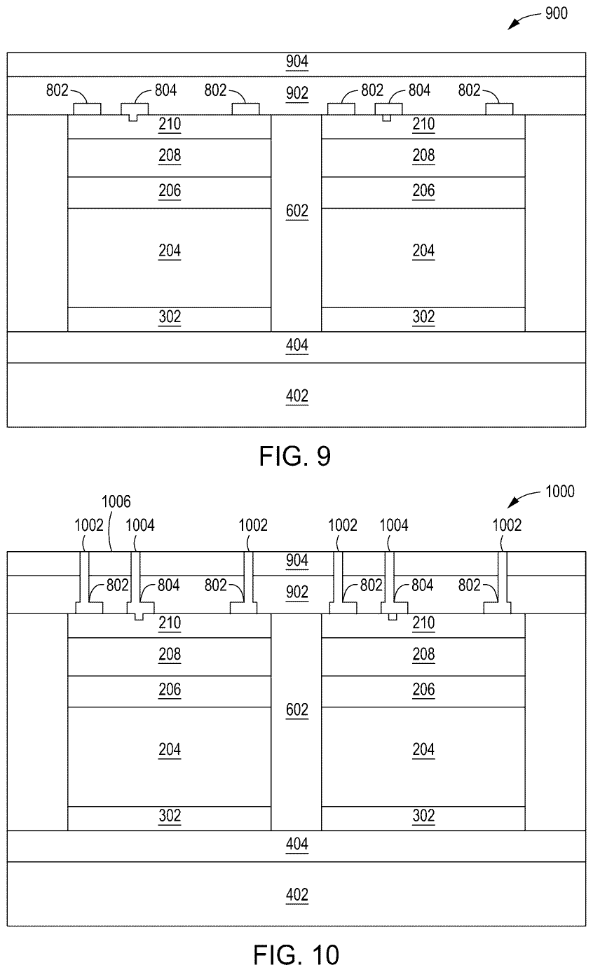

In block 118, dielectric material 902 is deposited on a topside of the carrier wafer 402 (reconstituted wafer) as depicted in a view 900 of FIG. 9. In some embodiments, the dielectric material 902 may be the same material as the interdie gapfill material 602 or different from the interdie gapfill material 602. The deposition of the dielectric material 902 may be performed as a back-end-of-line (BEOL) process. In some cases, the BEOL processing may occur at a packaging facility separate from the location of the FEOL processing. In block 120, a third oxide bonding layer 904 is deposited on the dielectric material 902 also depicted in the view 900 of FIG. 9. In some embodiments, the third oxide bonding layer 904 may be, but is not limited to, a tetraethyl orthosilicate (TEOS) oxide bonding layer and the like. The third oxide bonding layer 904 enhances the dielectric-to-dielectric bonding during the subsequent hybrid bonding process with a silicon wafer (discussed below). In block 122, contact pads are formed for the gate 804 and source/drain 802 through the third oxide bonding layer 904 and the dielectric material 902 as depicted in a view 1000 of FIG. 10. The BEOL processing may include etching through the third oxide bonding layer 904 and the dielectric material 902, deposition of a liner (e.g., using PECVD and/or ALD), and copper gapfill to produce source/drain contacts 1002 and gate contact 1004 on an uppermost surface 1006 of the carrier wafer 402 (reconstituted wafer).

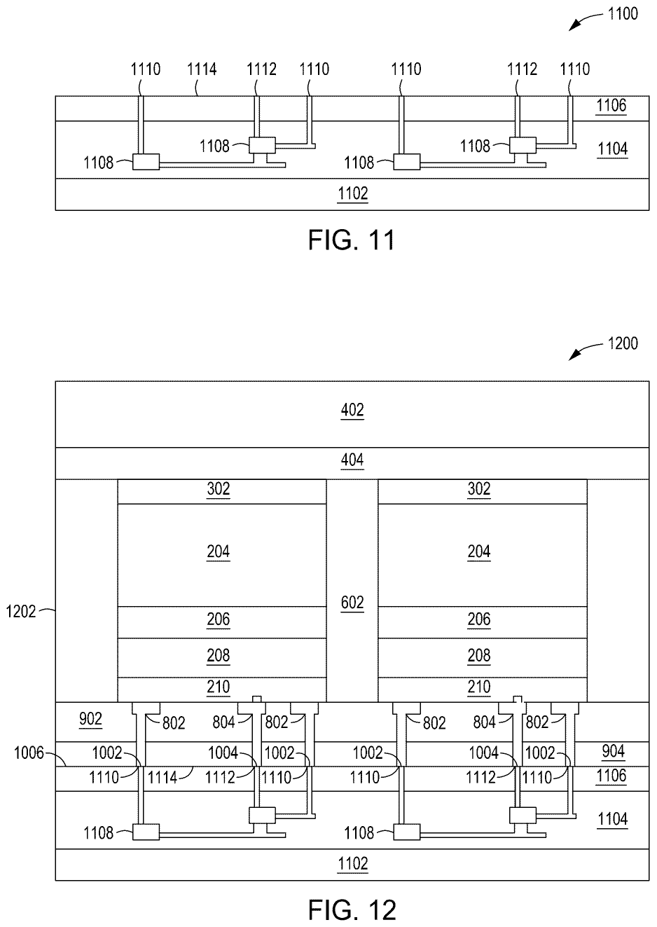

In block 124, a silicon wafer 1102 with transistor control structures 1108 is obtained as depicted in a view 1100 of FIG. 11. The silicon wafer 1102 comprises transistor control structures 1108 formed in a dielectric layer 1104, a fourth oxide bonding layer 1106, and gate contact 1112 and source/drain contacts 1110 for the transistor control structures 1108 on an uppermost surface 1114 of the silicon wafer 1102. In some embodiments, the silicon wafer 1102 may be a CMOS silicon-based wafer that is constructed using conventional silicon-based processing to produce economical control logic (e.g., pre-drivers, etc.) for the transistor structures in the carrier wafer 402. The transistor control structures 1108 enable transistors such as, but not limited to, RF power GaN transistors and/or RF switching GaN transistors, etc. Other contacts may also be formed in the uppermost surface 1114 of the silicon wafer 1102 and/or the uppermost surface 1006 of the carrier wafer 402 (reconstituted wafer).

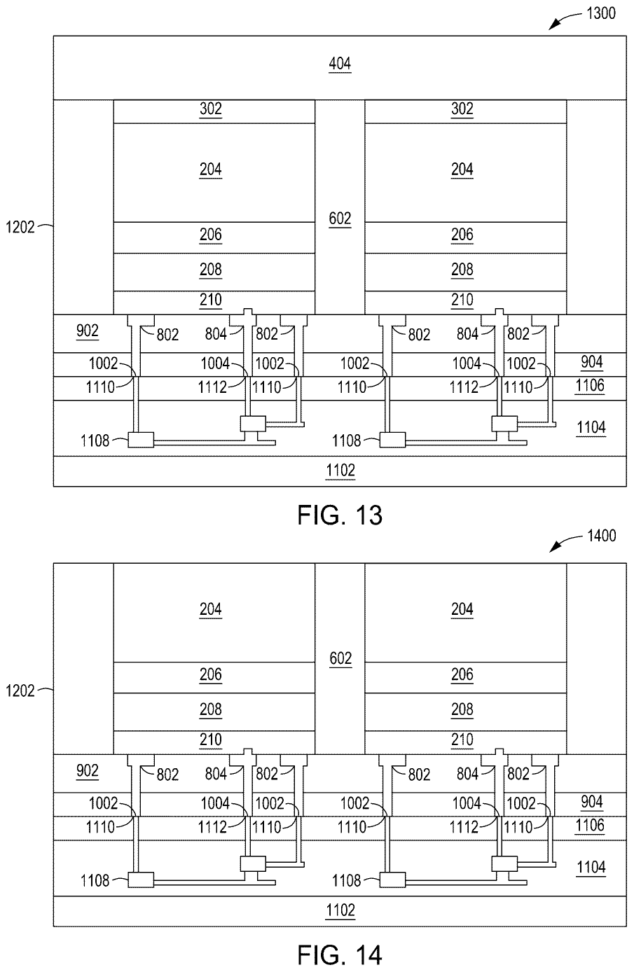

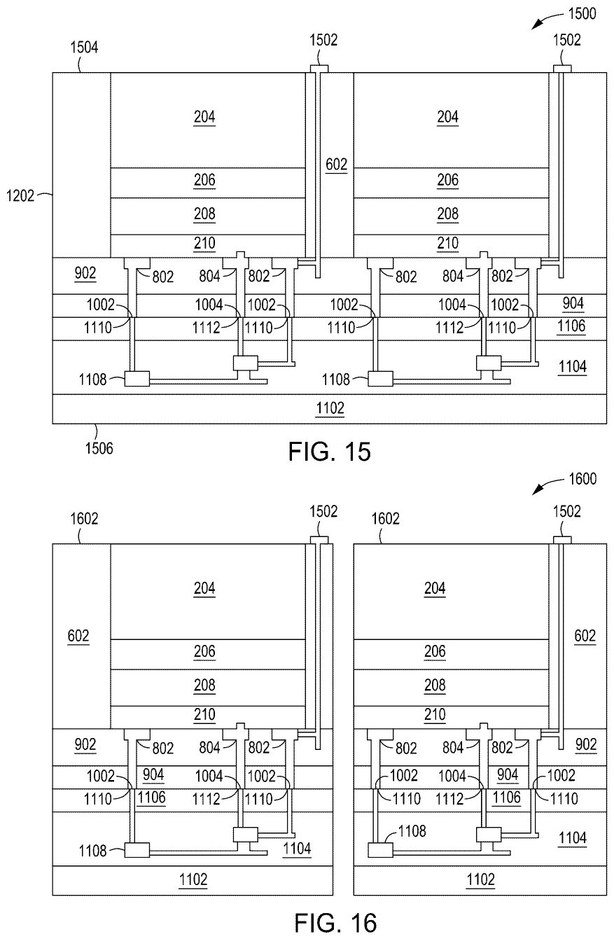

In block 126, the uppermost surface 1006 of the carrier wafer 402 (reconstituted wafer) and the uppermost surface 1114 of the silicon wafer 1102 are hybrid bonded together to form a bonded wafer 1202 as depicted in a view 1200 of FIG. 12. Hybrid bonding is the bonding of both metal and dielectric materials. The third oxide bonding layer 904 of the carrier wafer 402 and the fourth oxide bonding layer 1106 of the silicon wafer 1102 enhance the strength of the dielectric bonding during hybrid bonding. The metal contacts on the carrier wafer 402 and the silicon wafer 1102 essentially reflow into each other during the hybrid bonding process joining or bonding the contacts together to form the electrical connections between the transistor structures 202 and the transistor control structures 1108. Some additional BEOL processing may be performed after bonding to provide external contact points for the GaN transistors. The carrier wafer material may be removed by grinding and/or CMP processes to expose the second oxide bonding layer 404 as depicted in a view 1300 of FIG. 13. The second oxide bonding layer 404 and part of the transistor structure material (thinning) may then be removed by CMP processes to expose the transistor structure 202 as depicted in a view 1400 of FIG. 14. Contacts 1502 may then be formed by etching and deposition processes to provide external electrical connections to the underlying or overlying transistor and control structures as depicted in a view 1500 of FIG. 15. Although the view 1500 depicts the contacts 1502 on the topside 1504, the contacts 1502 may also be formed on the backside 1506. In further BEOL processing, the bonded wafer 1202 may then be singulated by, but not limited to, plasma dicing and the like to form individual GaN transistors 1602 as depicted in a view 1600.

By forming GaN transistor structures using smaller wafer technology, the epi quality of the GaN is very high and is well controlled with known yields. 300 mm GaN epitaxial processing is at an infancy stage. Although growth of GaN has been demonstrated on 300 mm wafers, the quality of the epi growth is low compared to existing 150/200 mm processes. The larger the diameter of the wafer, the more complicated managing the bowing or warpage of the wafer becomes due to larger amounts of curvature. The bowing also causes internal stresses which affects the epi growth. The larger diameter combined with high growth temperatures of GaN also causes thermal conductivity stresses, lowering epi quality. In addition, the larger wafer diameter may also require that the thickness of the epi growth be reduced to reduce bow, further lowering epi quality. Thicker epi growth is more desirable because thicker epi has less internal dislocations and defects, yielding higher quality epi growth.

In the present techniques, dicing the GaN transistor structures allows for selection of the best examples to further increase yield. Reconstituting the GaN transistor structures onto a larger diameter wafer allows for optimal use and placement of the expensive GaN material, dramatically reducing costs. The reconstituted wafer enables large wafer toolsets designed for silicon processing to be used, for example but not limited to, for GaN transistor gate scaling without requiring capital investment in large wafer GaN epi reactors, further reducing overall manufacturing costs. The hybrid bonding process allows for the separate formation of the GaN transistor structures and the silicon-based control structures so that each can be optimized to reduce costs. By using silicon-based control logic, no new processes need to be introduced, such as forming logic on GaN wafers and the like, further reducing manufacturing costs and increasing throughput (large wafer GaN has low epi quality). The present methods and structures provide an overall higher performance GaN transistor which is produced at a substantially smaller cost compared to using 300 mm GaN wafers.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method of forming transistors, comprising:
forming a reconstituted wafer by bonding dies having gallium nitride (GaN) transistor structures to a carrier wafer; and
hybrid bonding the reconstituted wafer to a silicon wafer having silicon-based transistor control structures.

2. The method of claim 1, wherein the dies have GaN transistor structures that are high electron mobility transistors (HEMTs) formed on a silicon substrate, a silicon carbide substrate, or a sapphire substrate.

3. The method of claim 1, wherein the dies are coated with an oxide bonding layer on a backside, the carrier wafer is coated with an oxide bonding layer on a topside, the backside of the dies are fusion bonded to the topside of the carrier wafer, and an interdie dielectric gapfill process is performed on the carrier wafer after the dies are fused to the carrier wafer to form the reconstituted wafer containing the dies.

4. The method of claim 3, wherein the oxide bonding layer is formed from tetraethyl orthosilicate (TEOS) oxide material.

5. The method of claim 1, wherein the reconstituted wafer is approximately 300 mm in diameter.

6. The method of claim 1, wherein the GaN transistor structures are processed in-situ in the reconstituted wafer to have transistor gate lengths that are approximately 50 nm or less.

7. The method of claim 1, wherein the reconstituted wafer undergoes extreme ultraviolet lithography prior to being hybrid bonded to the silicon wafer.

8. The method of claim 1, wherein the reconstituted wafer undergoes a preclean or a passivation process to further form the GaN transistor structures on the reconstituted wafer prior to being hybrid bonded to the silicon wafer.

9. The method of claim 1, wherein a first oxide bonding layer is formed on a first topside of the reconstituted wafer and a second oxide bonding layer is formed on a second topside of the silicon wafer prior to hybrid bonding.

10. The method of claim 9, wherein at least one source, drain, and gate are formed on the reconstituted wafer on at least one die of the dies prior to forming the first oxide bonding layer.

11. The method of claim 9, wherein contacts are formed through the first oxide bonding layer to underlying structure of the GaN transistor structures prior to the reconstituted wafer being bonded to the silicon wafer.

12. The method of claim 1, wherein the carrier wafer is removed after bonding the reconstituted wafer to the silicon wafer.

13. The method of claim 1, wherein the GaN transistor structures form RF power amplifiers or RF power switches and the silicon-based transistor control structures form logic circuitry to control the RF power amplifiers or the RF power switches.

14. A gallium nitride transistor, comprising:
a gallium nitride channel layer;
an aluminum gallium nitride barrier layer formed on the gallium nitride channel layer;
a source contact and a drain contact electrically connected to the gallium nitride channel layer;
a gate positioned horizontally between the source contact and the drain contact on the aluminum gallium nitride barrier layer, wherein the gate has a length that is approximately 50 nm or less,
wherein the gallium nitride transistor is formed by:
forming a reconstituted wafer by bonding dies having gallium nitride (GaN) transistor structures to a carrier wafer; and
hybrid bonding the reconstituted wafer to a silicon wafer having silicon-based transistor control structures.

15. The gallium nitride transistor of claim 14, wherein the dies are high electron mobility transistors (HEMTs) formed on a silicon substrate, a silicon carbide substrate, or a sapphire substrate.

16. The gallium nitride transistor of claim 14, wherein the gallium nitride transistor includes an oxide bonding layer.

17. The gallium nitride transistor of claim 14, wherein the gallium nitride transistor is an RF power amplifier or an RF power switch with silicon-based logic circuitry to control the RF power amplifier or the RF power switch.

18. A non-transitory, computer readable medium having instructions stored thereon that, when executed, cause a method of forming transistors to be performed, the method comprising:
forming a reconstituted wafer by bonding dies having gallium nitride (GaN) transistor structures to a carrier wafer; and
hybrid bonding the reconstituted wafer to a silicon wafer having silicon-based transistor control structures.

19. The non-transitory, computer readable medium of claim 18, wherein the dies are coated with an oxide bonding layer on a backside, the carrier wafer is coated with an oxide bonding layer on a topside, the dies are fusion bonded to the carrier wafer, and an interdie dielectric gapfill process is performed to form the reconstituted wafer containing the dies.

20. The non-transitory, computer readable medium of claim 18, wherein the GaN transistor structures are processed in-situ in the reconstituted wafer to have transistor gate lengths are approximately 50 nm or less.
